(19) United States
(12) Patent Application Publication
(10) Pub. No.: US 2014/0263168 A1
(43) Pub. Date: Sep. 18, 2014

(54) METHOD FOR MANUFACTURING PACKAGE SUBSTRATE

(71) Applicant: Unimicron Technology Corporation, Taoyuan (TW)

(72) Inventors: Shih-Lian Cheng, Taoyuan (TW); Jui-Jung Chien, Taoyuan (TW)

(73) Assignee: Unimicron Technology Corporation, Taoyuan (TW)

(21) Appl. No.: 14/088,782

(22) Filed: Nov. 25, 2013

(30) Foreign Application Priority Data
Mar. 15, 2013 (TW) 02109164

(51) Int. Cl. H05K 3/00; H05K 3/10

(52) U.S. Cl. CPC H05K 3/0017; H05K 3/0041; H05K 3/107; H05K 3/002
USPC 216/18; 216/17

(57) ABSTRACT

A method for manufacturing a package substrate is provided, including etching a substrate to form trenches each having a buffer portion, and forming a circuit in each of the trenches. The trenches are formed by etching instead of excimer laser to increase the aspect ratio of the trench, thereby solving the problem that the metallic layer is not thick enough and achieving a high yield of the circuit and a good process capability index.

### BACKGROUND OF THE INVENTION

1. Field of the Invention

This invention relates to methods for manufacturing package substrates, and, more particularly, to a method for manufacturing a package substrate having improved quality of circuits.

2. Description of Related Art

With the demands for light weight, compact, and continuously improved functions of electronic products, the layout density of a semiconductor chip becomes higher and higher, like the nanometer scale, such that a space between the package substrate and a solder pad is getting smaller. Therefore, a 3D chip-stacking technique such as through-silicon via (TSV) is thereby developed, and a package substrate can combine a semiconductor chip having electrode pads with high layout density to achieve the objective of integrating a semiconductor chip with high layout density without modifying the original supply chain and infrastructure of IC industry.

FIGS. 1A and 1C are cross-sectional views of a method for manufacturing a package substrate 1 according to the prior art.

As shown in FIG. 1A, a patterned resist layer 11 is formed on a substrate 10. The substrate 10 is made of a dielectric material, and the resist layer is formed by coating a photoresist thin film or sputtering a copper layer.

As shown in FIG. 1B, a trench 13 is formed on an exposed portion of the substrate 10 by an excimer laser method, and the resist layer is removed.

As shown in FIG. 1C, a metallic layer 15 is formed in the trench 13 as an embedded circuit.

With the trends of compact-size and low-profile requirements for electronic products, the embedded circuit of the package substrate 1 has to meet the requirements of fine wirings and fine spacing. In specific, the width of wires and the spacing between wires should be smaller than 10 μm, and the aspect ratio should be greater than 1. Upon the requirements, the trench 13 is formed by an excimer laser method, resulting that walls 13a and 13b of the trench 13 are directly joined in one line at the bottom, as shown in FIG. 1B, such that the trench 13 has a V-shape cross section.

However, when the cross section of the trench 13 is in a V-shape, a circuit with the width of wires and the spacing between wires smaller than 10 μm has a aspect ratio of a circuit for 1.2 at most (which is often smaller than 1.2, even smaller than 1). For example, a circuit with the width of wires and the spacing between wires as 5 μm has a depth for 6 μm at most, and a circuit with the width of wires and the spacing between wires as 3 μm has a depth for 3.6 μm at most, thereby causing the problem that the metallic layer 15 has an insufficient thickness and resulting in a lost of a circuit yield and a extremely low process capability index (Cpk).

Moreover, the cost of fine wires processed by a laser diode array (LDA) method is too high.

Therefore, how to overcome above problems of the prior art is substantially an issue desirably to be solved in the industry.

### SUMMARY OF THE INVENTION

In view of the problems of the above-mentioned prior art, the present invention provides a method for manufacturing a package substrate, comprising: providing a substrate; and etching the substrate to form a plurality of first trenches each having a buffer portion.

In an embodiment, the method further comprises: forming a resist layer on the substrate; forming an open area on the resist layer, thereby exposing a portion of a surface of the substrate in the open area; forming the first trench in the open area; and removing the resist layer.

In an embodiment, the first trench is formed by forming a cavity on the substrate by a laser method, the cavity having no buffer portion; and removing a portion of the substrate in the cavity to form the first trench.

In an embodiment, the substrate is etched by a plasma etching, dry etching or wet etching method.

In an embodiment, the substrate has a circuit layer therein, and a via is formed in the substrate, such that a portion of a surface of the circuit layer is exposed from the via. In an embodiment, the method further comprises: forming on the substrate a second trench connected to the via, and the second trench is formed by a laser or etching method, such as a plasma etching, dry etching or wet etching method. In an embodiment, the method further comprises forming in the second trench and the via a metallic layer connected to the circuit layer.

In an embodiment, the buffer portion is a bent surface joined to a side wall of the first trench at a bottom thereof.

In an embodiment, the method further comprises forming a metallic layer in the first trench.

From the above, in the method for manufacturing package substrates according to the present invention, the first trench is formed by an etching method such that the first trench has a buffer portion. Therefore, the first trench does not have a V-shaped cross section, and thus various drawbacks in the prior art can be overcome.

### BRIEF DESCRIPTION OF DRAWINGS

The invention can be more fully understood by reading the following detailed description of the preferred embodiments, with reference made to the accompanying drawings, wherein:

FIGS. 1A-1C are cross-sectional views illustrating a method for manufacturing a package substrate according to the prior art; and

FIGS. 2A-2G are cross-sectional views illustrating a method for manufacturing a package substrate according to the present invention, wherein FIG. 2C′ is another embodiment of FIG. 2C.

### DETAILED DESCRIPTION OF THE INVENTION

The following illustrative embodiments are provided to illustrate the disclosure of the present invention, these and other advantages and effects can be apparently understood by those in the art after reading the disclosure of this specification. The present invention can also be performed or applied by other different embodiments. The details of the specification may be on the basis of different points and applications, and numerous modifications and variations can be devised without departing from the spirit of the present invention.

It should be advised that the structure, ratio, and size as illustrated in this context are only used for disclosures of this specification, provided for persons skilled in the art to understand and read, and technically do not have substantial meaning. Any modification of the structure, change of the ratio relation, or adjustment of the size should be involved in the scope of disclosures in this specification without influencing the producible efficacy and the achievable objective of this specification. Also, the referred terms such as “on”, “first”, “second”, “bottom” and “one” in this specification are only for the convenience to describe, not for limiting the scope of embodiment in this invention. Those changes or adjustments of relative relationship without substantial change of technical content should also be considered within the category of implementation.

FIGS. 2A-2G are cross-sectional views illustrating a method for manufacturing a package substrate according to the present invention.

As shown in FIG. 2A, a resist layer 21 is formed on a substrate 20. In an embodiment, the substrate 20 has at least one circuit layer 22 therein, and the substrate 20 is made of a dielectric material.

In an embodiment, the resist layer 21 is formed by coating a photoresist thin film or sputtering a copper layer.

In addition, types relating a substrate and internal structures thereof are various and are not limited by the drawings.

As shown in FIG. 2B, at least one via 200 is formed in the substrate 20, such that a portion of a surface of the circuit layer 22 is exposed from the via 200.

In an embodiment, the via 200 is formed by penetrating the resist layer 21 and substrate 20 by a laser method.

As shown in FIG. 2B-1, a shielding layer 21a is formed on the resist layer 21 to shield a portion of the resist layer 21. In an embodiment, the shield layer 21a is a mask.

As shown in FIG. 2B-2, a patterning process is performed, such that a portion of the resist layer 21 exposed from the shielding layer 21a is removed by a semiconductor laser diode array (LDA) method, and a plurality of open areas 210 and 211 are formed on the resist layer 21, thereby a portion of the surface of the substrate 20 and the via 200 are exposed at the open areas 210 and 211.

As shown in FIG. 2C, the shielding layer 21a is removed. In other embodiments, the patterning process includes a photolithography method.

As shown in FIG. 2D, a substrate 20 at the open areas 210 and 211 is etched to form a first trench 23 having a buffer portion 230 and a second trench 24 connected to the via 200.

In an embodiment, the substrate 20 is etched by a plasma etching, anisotropic dry etching or isotropic wet etching method.

Moreover, the width of the first trench 23 is gradually reduced toward the bottom, and the buffer portion 230 is a bent surface joined to a side wall 23a of the first trench 23 at a bottom thereof, i.e., the side wall 23a of the first trench 23 will not be directly joined in one line at the bottom.

In another embodiment, as shown in FIG. 2C′, a cavity 23′ and a second trench 24 are formed on the substrate 20 in the open areas 210 and 211 by an excimer laser method, and the cavity 23′ does not have a buffer portion (i.e., the side wall 23a′ of the cavity 23′ is joined in one line at the bottom, where the cross section is V-shaped). Further as shown in FIG. 2D, a portion of the substrate 20 in the cavity 23′ is etched and removed to form the first trench 23.

Moreover, if the second trench 24 is formed by a laser method, the open area 211 is not necessary to be formed at an area of the resist layer 21 corresponding to the via 200. Furthermore, if the structure of the resist layer 21 is a thin film (such as Acrylic) with 2 μm, the thin film is able to block the LDA and plasma for 1 minute such that the first trench 23 is fabricated in 1 minute thereby reduces the process time.

As shown in FIG. 2E, a metallic layer 25 is formed on the resist layer 21 and in the first trench 23, the second trench 24 and the via 200, and the metallic layer 25 in the second trench 24 and the via 200 is connected to the circuit layer 22.

In an embodiment, the metallic layer 25 is formed by a plating copper material of a conductive layer 25a.

As shown in FIG. 2F, a metallic layer 25 over the resist layer 21 and a conductive layer 25a therebelow are removed, such that the remaining metallic layer 25 serves as an embedded circuit 26.

In an embodiment, the metallic layer 25 over the resist layer 21 is removed by an etching, brushing, or polishing method.

As shown in FIG. 2G, the resist layer 21 is removed.

In an embodiment, a portion of the metallic layer 25 and the resist layer 21 are removed by a leveling or stripping process, such that the surface of the metallic layer 25 (i.e., the circuit 26) is flush with the substrate 20.

Moreover, as the resist layer 21 is a protective film, the surface of the substrate 20 is prevented from scratching, and lumps of the remaining copper on the substrate 20 are effectively removed.

In the method for manufacturing package substrates 2 according to the present invention, the first trench 23 is formed by an etching method such that the first trench 23 has a buffer portion 230 preventing from forming a V-shaped cross-sectional trench, and thus the first trench 23 in this invention does not have the large taper angle problem. That is to say, the depth of the first trench 23 is increased such that the aspect ratio of the circuit 26 is greater than 2 when the width of wires and spacing between wires of the circuit 26 are smaller than 10 μm. Therefore, the method according to the present invention effectively improves the circuit yield and significantly increases the process capability index (Cpk).

Moreover, compared with the prior art that employs an excimer laser method to manufacture a package substrate of circuits, the present invention provides circuits 26 of better quality. Thus the throughput of the package substrate 2 is improved, thereby reducing the cost.

From the above, according to the present invention, the trench is formed by etching instead of excimer laser to increase the aspect ratio (at least greater than 2) of the trench, thereby eliminating the problem that the metallic layer has an insufficient thickness and achieving a high yield of the circuit and a good process capability index.

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed is:

1. A method for manufacturing a package substrate, comprising:
providing a substrate; and
etching the substrate to form a plurality of first trenches each having a buffer portion.

2. The method of claim 1, wherein the substrate has a circuit layer formed therein, and a plurality of vias are formed on the substrate, such that a portion of a surface of the circuit layer is exposed from the vias.

3. The method of claim 2, further comprising forming on the substrate a plurality of second trenches connected to the vias.

4. The method of claim 3, wherein the second trenches are formed by laser or etching.

5. The method of claim 4, wherein the etching is a plasma etching, dry etching or wet etching.

6. The method of claim 3, further comprising forming in each of the second trenches and a corresponding one of the vias a metallic layer connected to the circuit layer.

7. The method of claim 1, further comprising forming a resist layer on the substrate, forming on the resist layer an open area for a portion of a surface of the substrate to be exposed therefrom, forming the first trenches in the open area, and removing the resist layer.

8. The method of claim 1, wherein the first trenches are formed by forming a plurality of cavities in the substrate by laser, each of the cavities having a V-shaped cross section, and removing a portion of the substrate in the cavity to form the first trenches.

9. The method of claim 8, wherein the substrate is etched by plasma etching, dry etching or wet etching.

10. The method of claim 1, wherein the buffer portion is a bent surface joined to a side wall of each of the first trenches at a bottom thereof.

11. The method of claim 1, further comprising forming a metallic layer in each of the first trenches.

12. The method of claim 1, wherein the substrate is etched by plasma etching, dry etching or wet etching.
